(19) United States
(12) Patent Application Publication
(10) Pub. No.: US 2016/0103187 A1
(43) Pub. Date: Apr. 14, 2016

(54) Inspection Device

(71) Applicant: TOYOTA JIDOSHA KABUSHIKI KAISHA, Toyota-shi (JP)

(72) Inventors: Yusuke ITOH, Nagoya-shi (JP); Hiroo YOSHIKAWA, Toyota-shi (JP); Kenji TSUBOSAKA, Toyota-shi (JP); Tetsuo NOGUCHI, Nagoya-shi (JP)

(73) Assignee: TOYOTA JIDOSHA KABUSHIKI KAISHA, Toyota-shi (JP)

(21) Appl. No.: 14/878,322

(22) Filed: Oct. 8, 2015

(30) Foreign Application Priority Data
Oct. 14, 2014 (JP) 2014-209771

(51) Int. Cl. G01R 31/36

(52) U.S. Cl. CPC G01R 31/3675

(57) ABSTRACT

An inspection device 20 for inspecting a workpiece 100 having a stepped portion 115, comprises: a pair of electrode plates 220, 230 for nipping the workpiece 100 therebetween and applying voltage to the workpiece 100, the pair of electrode plates 220, 230 including a first electrode plate 220 to be disposed on the stepped portion side 115 and a second electrode plate 230 to be disposed on the opposite side from the stepped portion 115 of the workpiece 100; and a heat transferring member 240 to be disposed so as not to create a gap between the stepped portion 115 and the first electrode plate 220.

### CROSS-REFERENCE TO RELATED APPLICATIONS

The present application claims priority from Japanese patent application No. 2014-209771 filed on Oct.14, 2014, the disclosure of which is hereby incorporated by reference into this application in its entirety.

### BACKGROUND

1. Field

The present invention relates to an inspection device for inspecting a workpiece, such as a membrane electrode assembly.

2. Related Art

JP2002-90346A discloses an inspection device for inspecting the existence of a defect, such as a through-hole in a ceramic sheet. This inspection device nips both sides of the ceramic sheet by two sheets of electrode plates arranged in parallel to each other, and detects a discharge current which is generated when high direct-current voltage is applied between the electrodes, to inspect the existence of a defect in the ceramic sheet.

However, when using the conventional inspection device for inspection of the membrane electrode assembly of a fuel cell, the following subjects arises. The membrane electrode assembly contains carbon miaterial(s) and moisture. Therefore, when applying the voltage, carbon and water react as follows, and thereby current flows to generate heat.

C+2H₂O→CO₂4H⁺+4e⁻

Here, the membrane electrode assembly (workpiece) of the fuel cell has a stepped structure in order to secure an electrical insulation in an outer edge portion thereof. Therefore, the conventional inspection device produces a gap between the stepped portion and one of the electrodes. Since this gap functions as an air heat insulating layer, the stepped portion cannot fully radiate heat, thereby rising the temperature to induce a possible degradation of the workpiece.

### SUMMARY

In order to achieve at least part of the foregoing, the present invention provides various aspects described below.

(1) According to one aspect of the invention, there is provided an inspection device for inspecting a workpiece having a stepped portion. The inspection device comprises: a pair of electrode plates for nipping the workpiece therebetween and applying voltage to the workpiece, the pair of electrode plates including a first electrode plate to be disposed on the stepped portion side and a second electrode plate to be disposed on an opposite side from the stepped portion of the workpiece; and a heat transferring member to be disposed so as not to create a gap between the stepped portion and the first electrode plate. If the gap exists between the stepped portion and the first electrode plate on the stepped portion side among the pair of electrode plates, air which is high in heat insulation exists in the gap. Since the air functions as a heat insulating material and does not transfer heat when voltage is applied to the workpiece and the temperature of the stepped portion of the workpiece increases, the temperature of the stepped portion of the workpiece may excessively increase, and degrade the workpiece. According to this aspect, since the heat of the stepped portion can be radiated using the heat transferring member, the increase in the temperature of the stepped portion can be suppressed and the degradation of the workpiece can be reduced.

(2) The inspection device according to the aspect before, wherein the heat transferring member may be a sheet made of fluororesin Since fluororesin is a substance which has an electrical insulation capability, and is thermally and chemically stable, and has a thermal conductivity which is 10 times of air, it is preferred as the heat transferring member.

(3) The inspection device according to the aspect before wherein the first electrode plate may have a shape in which the first electrode plate is formed integrally with the heat transferring member and may be fittable with the stepped portion, and the first electrode plate contacts the stepped portion. Generally, the electrode plate is made of metal and is larger in the thermal conductivity than air. In this aspect, since one of the electrode plates has a shape in: which the electrode plate is formed integrally with the heat transferring member, and is fittable with the stepped portion, and the electrode plate contacts the stepped portion it also functions as the heat transferring member. Thus, electrode plate can suppress the increase in the temperature of the stepped portion, and can reduce the degradation of the workpiece.

Note that the present invention can be implemented in various forms. For example, the invention can be implemented, other than the inspection device for inspecting the workpiece such as a membrane electrode assembly, in a form of radiation structure in the inspection device

### BRIEF DESCRIPTION OF THE DRAWINGS

FIG. 1 is a view schematically illustrating a configuration of an inspection device for a membrane electrode assembly.

FIG. 2 is an enlarged view illustrating the pair of electrode plates and the membrane electrode assembly nipped therebetween.

FIG. 3 is an enlarged view illustrating a pair of electrode plates and a membrane electrode assembly nipped therebetween, in a comparative example.

FIG. 4 is a graph illustrating a relation between a thickness of the electrolyte membrane and a withstand voltage.

FIG. 5 illustrates one example of measurements of the current when the foreign matters are not contained in the membrane electrode assembly.

FIG. 6 illustrates one example of measurements of the current when the foreign matters are contained in the membrane electrode assembly.

FIG. 7 is a graph illustrating a relation of humidity, voltage applying rate, and a peak current that flows in a membrane electrode assembly.

FIG. 8 is a view illustrating a modification of the invention.

FIG. 9 is a view illustrating another modification of the invention.

### DESCRIPTION OF THE EMBODIMENTS

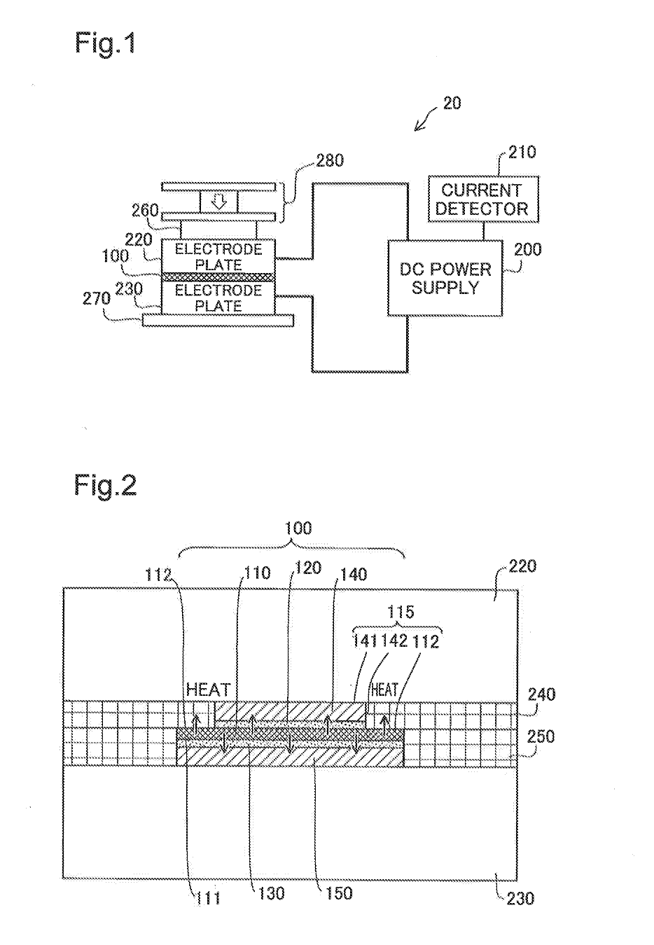

FIG. 1 is a view schematically illustrating a configuration of an inspection device for a membrane electrode assembly. The inspection device 20 includes a direct-current (DC) power supply 200, a current detector 210, a pair of electrode plates 220 and 230, a load cell 260, a base 270, and a pressing mechanism 280. The electrode plates 220 and 230 are placed on the base 270, and nip a membrane electrode assembly 100 (also referred to as “workpiece 100”). The DC power supply 200 supplies voltage between the electrode plates 220 and 230 to apply the voltage to the membrane electrode assembly 100. The current detector 210 detects current which flows between the electrode plates 220 and 230. The load cell 200 is placed on the electrode plate 220, and the pressing mechanism 280 is placed further on the load cell 260. The pressing mechanism 280 applies a surface pressure onto the membrane electrode assembly 100. The load cell 260 outputs the surface pressure applied to the membrane electrode assembly 100 as an electrical signal. The surface pressure applied to the membrane electrode assembly 100 can be measured based on the output signal of the load cell 260.

FIG. 2 is an enlarged view illustrating the pair of electrode plates and the membrane electrode assembly nipped therebetween. The membrane electrode assembly 100 is a target to be inspected by the inspection device 20, The membrane electrode assembly 100 includes an electrolyte membrane 110, a cathode-side catalyst layer 120, an anode-side catalyst layer 130, as cathode-side gas diffusion layer 140, and an anode-side gas diffusion layer 150. Two heat transferring sheets 240 and 250 are disposed so as to surround an outer edge of the membrane electrode assembly 100.

The electrolyte membrane 110 is an electrolyte membrane having a proton conductivity. The electrolyte membrane 110 may be made of electrolyte fluororesin (ion exchange resin), such as perfluorocarbonsulfone acid polymer. The cathode-side catalyst layer 120 and the anode-side catalyst layer 130 contain carbon which carries as catalyst (e.g., made of platinum). In this embodiment, the anode-side catalyst layer 130 coats entirely on a first surface 111 of the electrolyte membrane 110. On the other hand, the cathode-side catalyst layer 120 coats only on a part (power generation area) of a second surface 112 of the electrolyte membrane 110. This is because the anode-side catalyst layer 130 requires less amount of catalyst per unit area, compared with the cathode-side catalyst layer 120. Typically, the amount of catalyst per unit area of the anode-side catalyst layer 130 is ½ or less of that of the cathode-side catalyst layer 120 (e.g., may be about ⅓). Therefore, if the first surface 111 of the electrolyte membrane 110 is entirely coated, it is not too much waste of catalyst. In addition, if the first surface 111 of the electrolyte membrane 110 is entirely coated, the coating process of the anode-side catalyst layer 130 becomes easier than a case where the first surface 111 of the electrolyte membrane 110 is partially coated. Further, since only the part (power generation area) of the second surface 112 of the electrolyte membrane 110 is coated with the cathode-side catalyst layer 120, it becomes possible to secure the electrical insulation in an outer edge portion of the membrane electrode assembly 100.

The cathode-side gas diffusion layer 140 is placed on the cathode-side catalyst layer 120, and the anode-side gas diffusion layer 150 is placed on the anode-side catalyst layer 130. The cathode-side gas diffusion layer 140 and the anode-side gas diffusion layer 150 are formed by a sheet of carbon paper, respectively. Note that the cathode-side gas diffusion layer 140 and the anode-side as diffusion layer 150 may be formed by a carbon nonwoven fabric, instead of the carbon paper, respectively.

Neither the cathode-side catalyst layer 120 nor the cathode-side gas diffusion layer 140 exists in the outer edge portion of the second surface 112 of the electrolyte membrane 110 of the membrane electrode assembly 100. That is, the membrane electrode assembly 100 is provided with a stepped portion 115 in the outer edge portion thereof. The stepped portion 115 is comprised of a surface 141 of the cathode-side gas diffusion layer 140, a side surface 142 of the cathode-side gas diffusion layer 140, and the second surface 112 of the electrolyte membrane 110.

The heat transferring sheet 240 has a picture frame shape. The cathode-side catalyst layer 120 and the cathode-side gas diffusion layer 140 can be fitted into the frame-shaped heat transferring sheet 240. The heat transferring sheet 240 is in contact with a portion of the second surface 112 of the electrolyte membrane 110 of the membrane electrode assembly 100, which constitutes the stepped portion 115, without a gap. The heat transferring sheet 250 has a picture frame shape. The anode-side catalyst layer 130 and the anode-side gas diffusion layer 150 can be fitted into the frame shape of the heat transferring sheet 250. The heat transferring sheets 240 and 250 are made of fluotoresin, such as Teflon®. Fluororesin is a substance which has an electrical insulating capability and is thermally and chemically stable. The heat transferring sheets 240 and 250 are used as heat transferring members for radiating heat caused in the membrane electrode assembly 100, as will be described later. Fluororesin has a thermal conductivity which is about 10 times of air. The heat transferring sheets 240 and 250 may also be made of any materials, other than fluororesin, which have the electrical insulating capability and the heat conductivities sufficiently higher than air (e.g., 5 times or greater). For example, the heat transferring sheets 240 and 250 may also be made of ceramic material, such as aluminum nitride or alumina.

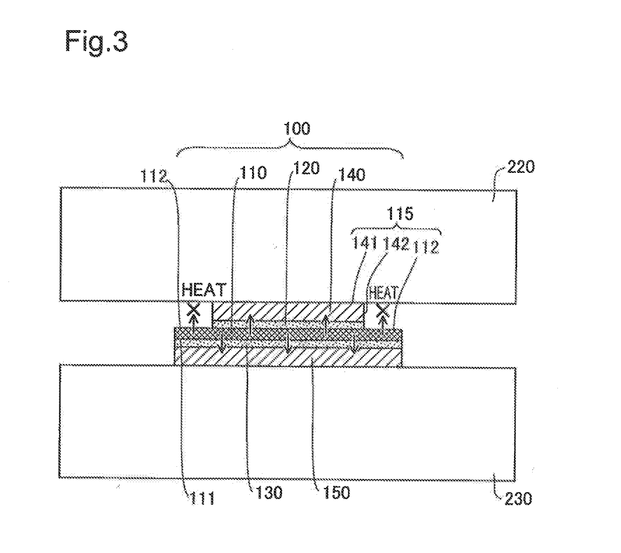

FIG. 3 is an enlarged view illustrating a pair of electrode plates and a membrane electrode assembly nipped therebetween, in a comparative example. This comparative example differs from the embodiment described above in that the two heat transferring sheets 240 and 250 are not provided.

When inspecting the membrane electrode assembly 100, a predetermined surface pressure is applied to the membrane electrode assembly 100 from the electrode plates 220 and 230, and voltage is applied. The electrolyte membrane 110, the cathode-side catalyst layer 120, and the anode-side catalyst layer 130 of the membrane electrode assembly 100 contain moisture, and the cathode-side catalyst layer 120 and the anode-side catalyst layer 130 contains carbon which carries the catalyst. In this state, when the voltage is applied to the membrane electrode assembly 100, a reaction of the following Formula (1) occurs, and current flows.

C+2H₂O→CO₂+4H⁺4e′ (1)

When the current flows in the membrane electrode assembly 100, the membrane electrode assembly 100 generates heat. The generation of heat is greater as the current flowing in the membrane electrode assembly 100 increases. The heat generated in the membrane electrode assembly 100 moves as illustrated by arrows in FIGS. 2 and 3. In the comparative example illustrated in FIG. 3, air exists above the second surface 112 of the electrolyte membrane 110, of the stepped portion 115 of the membrane electrode assembly 100, and the second surface 112 which constitutes a part of the stepped portion 115 contacts nowhere. That is, the upper side of the part of the second surface 112 is heat insulated by the air and, thus, heat is difficult to radiate. Thus, the membrane electrode assembly 100 may deteriorate in the stepped portion 115. On the other hand, in the embodiment illustrated in FIG. 2, the heat transferring sheet 240 is placed on the stepped portion 115. Heat radiates from the stepped portion 115 to the first electrode plate 220 through the heat transferring sheet 240. Therefore, the heat is not confined at the stepped portion 115, and thereby the degradation of the membrane electrode assembly 100 can be reduced. According to experiments, when the heat transferring sheets 240 and 250 were not used, discoloration and melting occurred in the electrolyte membrane 110 at the outer edge (stepped portion 115) of the membrane electrode assembly 100, but when the heat transferring sheets 240 and 250 were used, neither discoloration nor melting occurred in the electrolyte membrane 110.

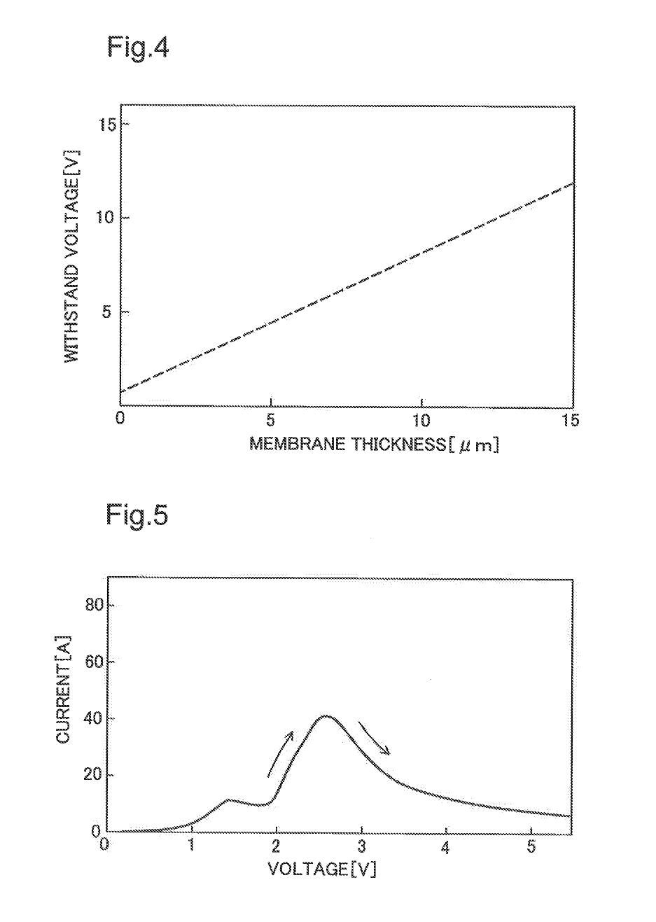

FIG. 4 is a graph illustrating a relation between a thickness of the electrolyte membrane and a withstand voltage. As the thickness of the electrolyte membrane 110 becomes thinner, the withstand voltage (voltage that results in a dielectric breakdown) decreases, and, on the other hand, as the membrane thickness becomes thicker, the withstand voltage increases. lf foreign matters are contained in the electrolyte membrane 110, the thickness of the electrolyte membrane 110 becomes thinner at portions where the foreign matters are contained. Since the portion where the foreign matters are contained is thinner in the membrane thickness, the dielectric breakdown occurs at a lower voltage and, thus, the withstand voltage decreases. The thickness (minimum thickness) of the electrolyte membrane 110 can be evaluated based on the magnitude of the withstand voltage.

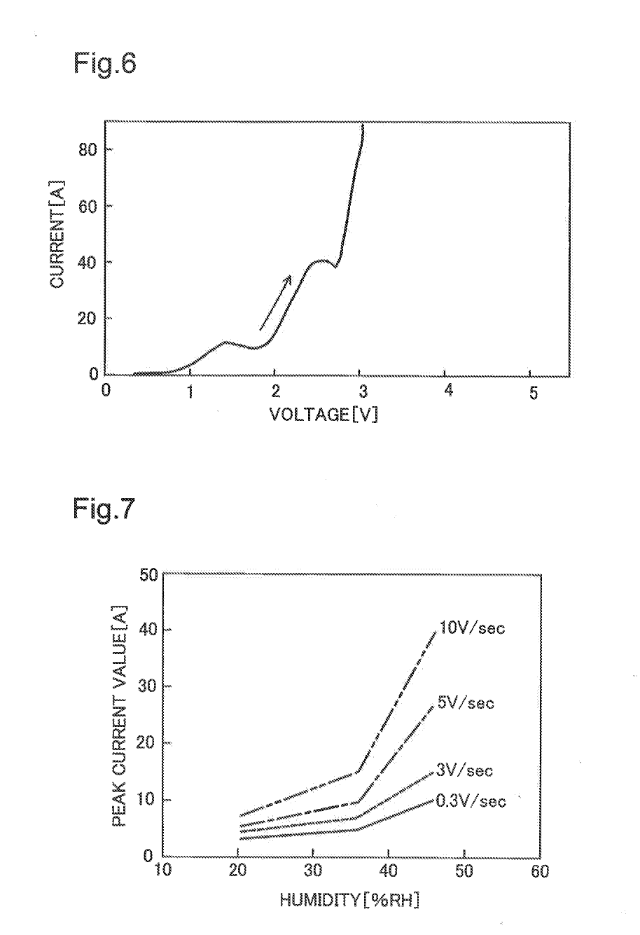

FIG. 5 illustrates one example of measurements of the current when the foreign matters are not contained in the membrane electrode assembly 100, and FIG. 6 illustrates one example of measurements of the current when the foreign matters are contained in the membrane electrode assembly 100. When the foreign matters are contained in the membrane electrode assembly 100, the thickness of the electrolyte membrane 110 becomes thinner in the portion concerned. In the experiments, a membrane electrode assembly 160 of about 250 cm² was nipped between the electrode plates 220 and 230, 1 MPa of surface pressure was applied, and voltage is applied while increasing the voltage at a rate of 0.2 V/sec. In the case where the foreign matters were not contained in the membrane electrode assembly 100, the dielectric breakdown did not occur even when the voltage applied to the membrane electrode assembly 100 was increased to a little more than 5V, as illustrated in FIG. 5. However, in the case where the foreign matters were contained in the membrane electrode assembly 100, the dielectric breakdown occurred when the voltage applied to the membrane electrode assembly 100 was increased to about 3V, as illustrated in FIG. 6. In the example illustrated in FIG. 6, it can be considered that the thickness of the electrolyte membrane 110 of the membrane electrode assembly 100 is reduced down to about 3 μdue to the foreign matters. As described above, according to this embodiment, it is possible to inspect whether the electrolyte membrane 110 has thin thickness portion(s) of 3 82 or less by applying the voltage at 5V or less to the membrane electrode assembly 100.

FIG. 7 is a graph illustrating a relation of humidity, voltage applying rate, and a peak current that flows in a membrane electrode assembly of about 13 cm². Humidity refers to a relative humidity (% RH) of atmosphere where the inspection device is placed. The peak current which flows in the membrane electrode assembly 100 increases as the voltage applying rate becomes greater (faster), regardless of the relative humidity of atmosphere. Therefore, the voltage applying rate is preferred to be less (slower). Note that, if the voltage applying rate is less, the total electrical charge (a value that is obtained by integrating the currents with respect to time) increases and, thus, an influence by carbon oxidization by Formula (1) described above becomes greater. Therefore, it is preferred that the voltage applying rate is not excessively less.

Further, as can be seen from the graph, when the relative humidity becomes 40 % RE or less, there is no large difference in the peak current which flows in the membrane electrode assembly 100. Therefore, the relative humidity is preferred to less, i.e., 40 % RH or less. Note that if the relative humidity of atmosphere is less, moisture evaporates from the electrolyte membrane 110, the cathode-side catalyst layer 120, and the anode-side catalyst layer 130, the reaction of the Formula (1) described above becomes difficult to occur and, thus, it can be considered that the peak current decreases. Therefore, instead of reducing the relative humidity of atmosphere, for example, it is preferred that moisture of the membrane electrode assembly 100 is reduced by heating the membrane electrode assembly 100 before applying the voltage (e.g., 5V) to the membrane electrode assembly 100. For example, the membrane electrode assembly 100 may be heated at temperature of 80° C. for 30 seconds.

As described above, according to this embodiment, the inspection device 20 includes the heat transferring sheets 240 and 250, and radiates heat which is generated in the stepped portion 115 of the membrane electrode assembly 100, by using the heat transferring, sheets 240 and 250 as the heat transferring members. Therefore, the heat is not confined in the stepped portion 115 of the membrane electrode assembly 100 and, thus, the degradation of the membrane electrode assembly 100 can be reduced. Further, in this embodiment, sheets made of fluororesin are used as the heat transferring sheets 240 and 250. Since fluororesin is a substance which has the electrical insulating capability and is thermally and chemically stable, and has a thermal conductivity which is 10 times of air, it is preferred for the heat transferring member.

### Modifications:

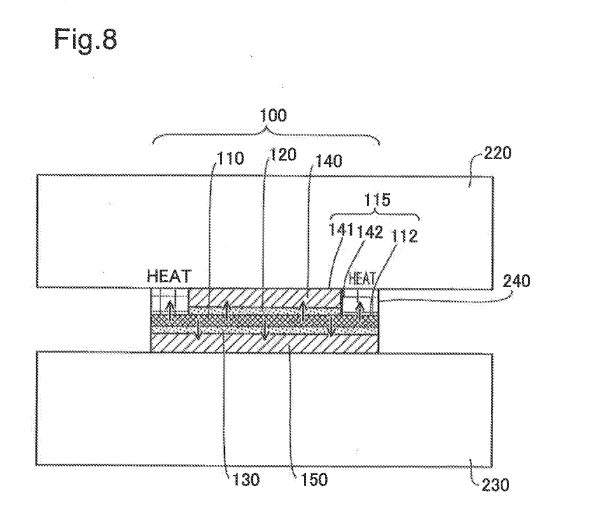

FIG. 8 is a view illustrating a modification of the invention. This modification illustrated in FIG. 8 differs from the embodiment illustrated in FIG. 2 in that the heat transferring sheet 250 is not provided. Also according to the modification, since the stepped portion 115 is in contact with the heat transferring sheet 240, heat can radiate from the stepped portion 115 via the heat transferring sheet 240. Note that in FIG. 8, although the size of the outer edge of the heat transferring sheet 240 is almost the same as the size of the outer edge of the membrane electrode assembly 100, it may be larger than the outer edge of the membrane electrode assembly 1.00 similar to the heat transferring sheet 240 illustrated in FIG. 2.

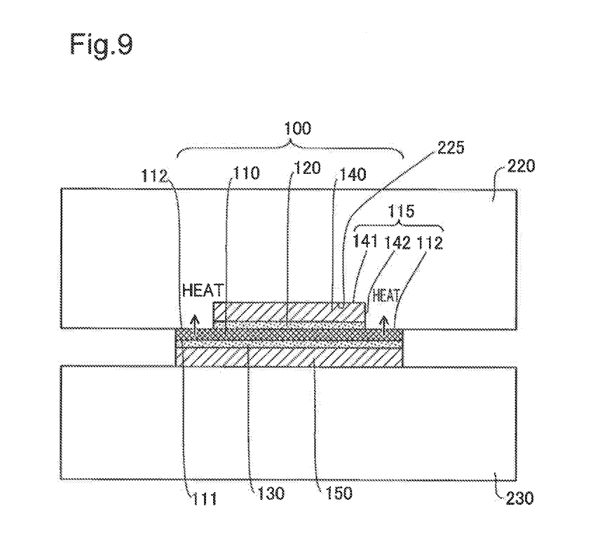

FIG. 9 is a view illustrating another modification of the invention. This modification illustrated in FIG. 9 is not provided with the heat transferring sheets 240 and 250, and instead, differs in the shape of the first electrode plate 220, as compared with the embodiment illustrated in FIG. 2. In the modification illustrated in FIG. 9, the first electrode plate 220 has a recessed portion 225 which can be fitted with the stepped portion 1153 on the membrane electrode assembly 100 side. That is, the cathode-side catalyst layer 120 and the cathode-side gas diffusion layer 140 of the membrane electrode assembly 100 are inserted into the recessed portion 225. That is, the first electrode plate 220 has a shape in which the electrode plate 220 and the heat transferring sheet 240 of the embodiment illustrated in FIG. 2 are formed integrally. According to this modification, since the first electrode plate 220 contacts the stepped portion 115, heat can radiate from the stepped portion 115 via the electrode plate 220. Note that the second electrode plate 230 may also be provided with a recessed portion into which the anode-side catalyst layer 130 and the anode-side gas diffusion layer 150 can be fitted.

The foregoing describes some aspects of the invention with reference to some embodiments and examples. The embodiments and the examples of the invention described above are provided only for the purpose of facilitating the understanding of the invention and not for the purpose of limiting the invention in any sense. The invention may be changed, modified and altered without departing from the scope of the invention and includes equivalents thereof.

What is claimed is:

1. An inspection device for inspecting a workpiece having a stepped portion, comprising:
a pair of electrode plates for nipping the workpiece therebetween and applying voltage to the workpiece, the pair of electrode plates including a first electrode plate to be disposed on the stepped portion side and a second electrode plate to be disposed on an opposite side from the stepped portion of the workpiece: and
a heat transferring member to be disposed so as not to create a gap between the stepped portion and the first electrode plate.

2. The inspection device in accordance with claim 1, wherein the heat transferring member is a sheet made of fluororesin.

3. The inspection device in accordance with claim 1, wherein the first electrode plate has a shape in which the first electrode plate is formed integrally with the heat transferring member and is fittable with the stepped portion, and the first electrode plate contacts the stepped portion.
